(19) United States
(12) Patent Application Publication
(10) Pub. No.: US 2019/0245016 A1
(43) Pub. Date: Aug. 8, 2019

(54) DISPLAY APPARATUS AND METHOD OF MANUFACTURING THE SAME

(71) Applicant: Samsung Display Co., Ltd., Yongin-Si (KR)

(72) Inventors: Yongsu LEE, Seoul (KR); Sunghwan CHOI, Seoul (KR); Sunghoon YANG, Seoul (KR); Thanh Tien NGUYEN, Seoul (KR); Myounggeun CHA, Seoul (KR)

(21) Appl. No.: 16/256,797

(22) Filed: Jan. 24, 2019

(30) Foreign Application Priority Data
Feb. 8, 2018 (KR) 10-2018-0015730

(51) Int. Cl. H01L 27/32; H01L 27/12

(52) U.S. Cl. CPC H01L 27/3246; H01L 27/3258; H01L 27/1222; H01L 27/3276

(57) ABSTRACT

A display apparatus includes a base substrate, a conductive layer disposed on the base substrate to cover entire of the base substrate, wherein the conductive layer is configured to be applied with a ground voltage, a buffer layer disposed on the conductive layer, an active pattern comprising a drain region, a source region and a channel region between the drain region and the source region, a first insulation layer disposed on the active pattern, a gate pattern disposed on the first insulation layer and comprising a gate electrode which overlapping the channel region of the active pattern, a second insulation layer disposed on the gate pattern, and a data pattern comprising a source electrode electrically connected to the source region of the active pattern, and a drain electrode electrically connected to the drain region of the active pattern.

This application claims priority to Korean Patent Application No. 10-2018-0015730, filed on Feb. 8, 2018, and all the benefits accruing therefrom under 35 U.S.C. § 119, the content of which in its entirety is herein incorporated by reference.

### BACKGROUND

### 1. Field

Example embodiments of the inventive concept relate to a display apparatus and a method of manufacturing the display apparatus. More particularly, example embodiments of the inventive concept relate to a display apparatus including a switching element formed by a low temperature polysilicon (LTPS) process.

### 2. Description of the Related Art

Recently, a display apparatus having light weight and small size has been manufactured. A cathode ray tube (CRT) display apparatus has been used due to a performance and a competitive price. However the CRT display apparatus has a weakness with a size or portability. Therefore a display apparatus such as a plasma display apparatus, a liquid crystal display apparatus and an organic light emitting display apparatus has been highly regarded due to small size, light weight and low-power-consumption.

Such a display apparatus may have a structure including a switching element formed by a low temperature polysilicon (LTPS) process. A DR range is a driving range of drain-source current Ids between a drain electrode and a source electrode of the switching element. The switching element has threshold voltage (Vth) applied to the gate electrode and the DR range as characteristics. There has been a problem that display quality of the display apparatus is deteriorated due to dispersion of the DR range and the threshold voltage for each of the switching elements. Particularly, the switching element formed by the low-temperature polysilicon process has a structure in which a channel region of an active pattern is floating. The dispersion of the DR range and the threshold voltage are relatively large and the display quality degradation problem can be more significant.

### SUMMARY

One or more example embodiment of the inventive concept provides a display apparatus including a switching element formed by a low temperature polysilicon (LTPS) process capable of improving a display quality by reducing dispersion of DR range and threshold voltage.

One or more example embodiments of the inventive concept also provides a method of manufacturing the display apparatus.

According to an example embodiment of the inventive concept, a display apparatus includes a base substrate, a conductive layer disposed on the base substrate to cover an entirety of the base substrate, wherein the conductive layer is configured to be applied with a ground voltage, a buffer layer disposed on the conductive layer, an active pattern comprising a drain region, a source region and a channel region between the drain region and the source region, a first insulation layer disposed on the active pattern, a gate pattern disposed on the first insulation layer and comprising a gate electrode overlapping the channel region of the active pattern, a second insulation layer disposed on the gate pattern, and a data pattern comprising a source electrode electrically connected to the source region of the active pattern, and a drain electrode electrically connected to the drain region of the active pattern.

In an example embodiment, the active pattern may include crystallized polysilicon (poly-Si).

In an example embodiment, the conductive layer may be an n+ doped amorphous silicon (n+a-Si) layer.

In an example embodiment, the conductive layer may have a carrier concentration of 1*10¹⁵ (ions/cm³) or more.

In an example embodiment, the buffer layer may include a silicon compound.

In an example embodiment, the base substrate may be a polyimide (PI) resin film.

In an example embodiment, the display apparatus may further include a lower buffer layer disposed between the base substrate and the conductive layer, and comprises a silicon compound.

In an example embodiment, the active pattern, the gate electrode, the source electrode, and the drain electrode may form a thin film transistor. The display apparatus may further include a first electrode electrically connected to the thin film transistor, a second electrode facing the first electrode, and a light emitting structure disposed between the first electrode and the second electrode.

In an example embodiment, the conductive layer may include polysilicon (poly-Si) doped with impurities.

In an example embodiment, the conductive layer may include indium tin oxide (ITO) or indium zinc oxide (IZO).

According to an example embodiment of the inventive concept, a method of manufacturing a display apparatus includes forming a conductive layer on a base substrate to cover an entirety of the base substrate, forming, in a chamber by a deposition process, a buffer layer which comprises a silicon compound on the conductive layer, forming, in a chamber by a deposition process, an active layer which comprises an amorphous silicon on the buffer layer, crystallizing the amorphous silicon to form an active pattern comprising polysilicon (poly-Si), and forming a first insulation layer on the active pattern.

In an example embodiment, in forming the conductive layer, the conductive layer may be formed by depositing amorphous silicon together with a phosphorus containing gas on the base substrate.

In an example embodiment, the conductive layer, the buffer layer, and the active layer may be formed by a continuous deposition process in a same chamber.

In an example embodiment, the base substrate may be a polyimide (PI) resin film.

In an example embodiment, the method may further include, before forming the conductive layer, forming a lower buffer layer comprising a silicon compound on the base substrate. The conductive layer may be formed on the lower buffer layer.

In an example embodiment, the conductive layer may have a carrier concentration of 1*10¹⁵ (ions/cm³) or more.

In an example embodiment, the conductive layer may include one of polysilicon (poly-Si) doped with impurities, indium tin oxide (ITO), and indium zinc oxide (IZO).

In an example embodiment, forming the active pattern may include forming a polysilicon layer comprising polysilicon (poly-Si) by crystallizing the amorphous silicon, and patterning the polysilicon layer to form the active pattern.

In an example embodiment, the method may further include forming a gate electrode on the first insulation layer, forming a drain region and a source region by doping impurities to a portion of the active pattern, forming a second insulation layer on the gate electrode, and forming a source electrode and a drain electrode on the second insulation layer.

In an example embodiment, the method may further include forming a planarization layer on the source electrode and the drain electrode, forming a first electrode on the planarization layer, forming a pixel defining layer, which defines an opening to expose the first electrode, on the planarization layer, forming a light emitting structure on the first electrode on which the pixel defining layer is formed, and forming a second electrode on the light emitting structure.

According to the example embodiments of the present inventive concept, a display apparatus includes a base substrate, a conductive layer disposed on the base substrate to cover entire of the base substrate, wherein a ground voltage or voltage of 0 V is applied, a buffer layer disposed on the conductive layer, an active pattern comprising a drain region, a source region and a channel region between the drain region and the source region, a first insulation layer disposed on the active pattern, a gate pattern disposed on the first insulation layer and comprising a gate electrode which overlaps the channel region of the active pattern, a second insulation layer disposed on the gate pattern, and a data pattern comprising a source electrode electrically connected to the source region of the active pattern, and a drain electrode electrically connected to the drain region of the active pattern. Since the conductive layer to which the ground voltage is applied is located under the active pattern of the thin film transistor, electrical characteristics of the thin film transistor are stabilized, and the display quality of the display apparatus can be improved.

In addition, the conductive layer is an n+amorphous silicon (n+a-Si) layer formed corresponding to the entire surface of the base substrate, and does not require a additional patterning process, the conductive layer can be formed by the same process as the buffer layer disposed on the conductive layer, thereby a display apparatus formed by a simplified manufacturing process can be provided.

It is to be understood that both the foregoing general description and the following detailed description are exemplary and explanatory and are intended to provide further explanation of the invention as claimed.

### BRIEF DESCRIPTION OF THE DRAWINGS

The above and other features of the inventive concept will become more apparent by describing in detail example embodiments thereof with reference to the accompanying drawings, in which:

FIG. 1 is a cross-sectional view illustrating a display apparatus according to an example embodiment of the inventive concept;

FIG. 2 is a cross-sectional view illustrating a display apparatus according to an example embodiment of the inventive concept;

FIG. 3 is a cross-sectional view illustrating a display apparatus according to an example embodiment of the inventive concept;

FIG. 4 is a cross-sectional view illustrating a display apparatus according to an example embodiment of the inventive concept;

FIGS. 5A, 5B, 5C, 5D, and 5E are cross-sectional views illustrating a method of manufacturing the display apparatus of FIG. 1;

FIGS. 6A, 6B and 6C are cross-sectional views illustrating a method of manufacturing the display apparatus of FIG. 2; and

FIGS. 7A and 7B are cross-sectional views illustrating a method of manufacturing the display apparatus of FIG. 4.

### DETAILED DESCRIPTION

Hereinafter, the inventive concept will be explained in detail with reference to the accompanying drawings.

FIG. 1 is a cross-sectional view illustrating a display apparatus according to an example embodiment of the inventive concept.

Referring to FIG. 1, the display apparatus may include a base substrate 100, a conductive layer 110, a buffer layer 120, an active pattern ACT, a first insulation layer 110, a buffer layer 120, an active layer ACT, a first insulation layer 130, a gate pattern, a second insulation layer 140, a data pattern, a planarization layer 150, a first electrode EL1, a pixel defining layer 160, a light emitting structure 170 and a second electrode EL2.

The base substrate 100 may include a transparent insulation substrate. For example, the base substrate 100 may include a glass substrate, a quartz substrate, a transparent resin substrate, and so on. Examples of the transparent resin substrate for the base substrate 100 may include polyimide-based resin, acryl-based resin, polyacrylate-based resin, polycarbonate-based resin, polyether-based resin, sulfonic acid containing resin, polyethyleneterephthalate-based resin, and so on. Preferably, the base substrate 100 may be a polyimide (PI) resin film.

The conductive layer 110 may be disposed on the base substrate 100. The conductive layer 110 may be a n+a-Si layer, (n+ doped amorphous silicon). Since the conductive layer 110 is formed corresponding to entire surface of the base substrate 100, no additional patterning is required in a process of forming the conductive layer 110. The n+a-Si layer may be formed by depositing amorphous silicon on the base substrate 100 together with a phosphorus containing gas.

The conductive layer 110 may be grounded with a voltage of 0 V or a ground voltage. For example, since the conductive layer 110 is formed corresponding to the entire surface of the base substrate 100, a side surface of the conductive layer 110 may be connected to a ground portion at an edge portion of the display apparatus or may be connected to a ground wiring portion through an additional contact hole.

The conductive layer 110 may have conductivity. Specifically, the conductive layer 110 may have a carrier concentration of 1*10¹⁰ (ions/cm³) or more. Preferably, the conductive layer 110 may have a carrier concentration of 1*10¹⁵ (ions/cm³) or more.

The buffer layer 120 may be disposed on the conductive layer 110. The buffer layer 110 may prevent diffusion of metal atoms and/or impurities from the base substrate 100. Additionally, the buffer layer 110 may adjust heat transfer rate of a successive crystallization process for the active pattern ACT, to thereby obtain a substantially uniform the active pattern ACT. In case the base substrate 100 is formed with a relatively irregular surface, the buffer layer 120 may improve flatness of the surface of the conductive layer 110. The buffer layer 120 may be formed using a silicon compound. For example, the buffer layer 120 may include silicon oxide (SiOx), silicon nitride (SiNx), silicon oxynitride (SiOxNy), silicon oxycarbide (SiOxCy), silicon carbon nitride (SiCxNy), and so on.

The active pattern ACT may be disposed on the buffer layer 120. The active pattern ACT may be a polysilicon (poly-Si) pattern. The active pattern ACT may include a drain region D and a source region S which are impurity doped regions and a channel region CH between the drain region D and the source region S.

The polysilicon (poly-Si) pattern may be formed by depositing amorphous silicon and then crystallizing it. Here, the amorphous silicon may be crystallized by rapid thermal annealing (RTA), solid phase crystallization (SPC), excimer laser annealing (ELA), metal induced crystallization (MIC), metal induced lateral crystallization (MILC), and a variety of other methods. The source region S and the drain region D may be formed by doping a portion of the polysilicon pattern with an impurity.

The first insulation layer 130 may be disposed on the base substrate 100 on which the active pattern ACT is disposed. The first insulation layer 130 may include a silicon compound, metal oxide such as hafnium oxide (HfOx), zirconium oxide (ZrOx), titanium oxide (TiOx), and so on. In example embodiments, the first insulation layer 130 may be uniformly formed on the buffer layer 120 along a profile of the active pattern. Here, the first insulation layer 130 may have a substantially small thickness, such that a stepped portion may be formed at a portion of the first insulation layer 130 adjacent to the active pattern. In some example embodiments, the first insulation layer 130 may have a relatively large thickness for sufficiently covering the active pattern, so that the first insulation layer 130 may have a substantially level surface.

The gate pattern may be disposed on the first insulation layer 130. The gate pattern may include metal, alloy, conductive metal oxide, a transparent conductive material, and so on. The gate pattern may include a gate electrode GE overlapping the active pattern ACT, a signal line for driving a pixel such as gate line, and so on.

The second insulation layer 140 may be disposed on the first insulation layer 130 on which the gate pattern is disposed. The second insulating layer 140 may electrically isolate the gate electrode GE from a source electrode SE and a drain electrode DE. The second insulation layer 140 may be uniformly formed on the first insulation layer 130 along a profile of the gate pattern. Here, the second insulation layer 140 may have a substantially small thickness, such that a stepped portion may be formed at a portion of the second insulation layer 140 adjacent to the gate pattern. The second insulating layer 140 may be formed using a silicon compound such as silicon oxide, silicon nitride, silicon oxynitride, silicon carbonitride, and/or silicon oxycarbide. In some example embodiments, the second insulation layer 140 may have a relatively large thickness for sufficiently covering the gate pattern, so that the second insulation layer 140 may have a substantially level surface.

The data pattern may be disposed on the second insulation layer 140. The data pattern may include the drain electrode DE, the source electrode SE, a signal line for driving the pixel such as a data line, and so on. The drain electrode DE may be electrically connected to the drain region D of the active pattern ACT through a contact hole formed through the first insulation layer 130, the second insulation layer 140. The source electrode SE may be electrically connected to the source electrode SE may be electrically connected to the source region S of the active pattern ACT through a contact hole formed through the first insulation layer 130, the second insulation layer 140.

The active pattern ACT, the gate electrode GE, the source electrode SE and the drain electrode DE may form a thin film transistor TFT.

The planarization layer 150 may be disposed on the second insulation layer 140 on which the thin film transistor TFT is disposed. The planarization layer 150 may have a single-layered structure or a multi-layered structure including at least two insulation films. The planarization layer 150 may include photoresist, acryl-based resin, polyimide-based resin, polyamide-based resin, siloxane-based resin, and so on. These may be used alone or in a combination thereof. Alternatively, planarization layer 150 may include an inorganic material. For example, the planarization layer 150 may be formed using silicon oxide, metal, metal oxide and so on.

The first electrode EL1 may be disposed on the planarization layer 150. The first electrode EL1 may be connected to the source electrode SE exposed through a contact hole formed through the planarization layer 150. In some example embodiments, a contact, a plug, or a pad may be formed in the contact hole, and the first electrode EL1 may be formed on the contact, the plug or the pad. Here, the first electrode EL1 may be electrically connected to the source electrode SE through the contact, the plug, or the pad.

The first electrode EL1 may include a reflective material or a transmissive material in accordance with the emission type of the display apparatus. For example, the first electrode EL1 may be formed using aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, and so on. These may be used alone or in a combination thereof. In example embodiments, the first electrode EL1 may have a single layer structure or a multi layer structure, which may include a metal film, an alloy film, a metal nitride film, a conductive metal oxide film and/or a transparent conductive film.

The pixel defining layer 160 may be disposed on the third insulation layer 150 on which the first electrode EL1 is disposed. The pixel defining layer 160 may include an organic material and/or an inorganic material. For example, the pixel defining layer 160 may be formed using photoresist, acryl-based resin, polyacryl-based resin, polyimide-based resin, a silicon compound, and so on.

In example embodiments, the pixel defining layer 160 may be etched to form an opening for partially exposing the first electrode PE. A display region and a non-display region of the display apparatus may be defined by the openings of the pixel defining layer 160. For example, a portion where the opening of the pixel defining layer 160 is located may correspond to the display region, and the non-display region may correspond to a portion of the pixel defining layer 160 adjacent to the opening.

The light emitting structure 170 may be positioned on the first electrode EL1 exposed by the opening of the pixel defining layer 160. The light emitting structure 170 may extend on a sidewall of the opening of the pixel defining layer 160. In example embodiments, the light emitting structure 170 may have a multilayer structure including an organic light emitting layer (EL), a hole injection layer (HIL), a hole transfer layer (HTL), an electron transfer layer (ETL), an electron injection layer (EIL), and so on. In example embodiments, the hole injection layer, the hole transfer layer, the electron transfer layer, the electron injection layer, and the like may be commonly formed so as to correspond to a plurality of pixels. In some example embodiments, a plurality of organic light emitting layers may be formed using light emitting materials for generating different colors of light such as a red color of light, a green color of light and a blue color of light in accordance with color pixels of the display apparatus. In some example embodiments, the organic light emitting layer of the of the light emitting structure 170 may include a plurality of stacked light emitting materials for generating a red color of light, a green color of light and a blue color of light to thereby emitting a white color of light. In this case, the light emitting structures are commonly formed so as to correspond to the plurality of pixels, and each pixel can be divided by a color filter layer.

The second electrode EL2 may be disposed on the pixel defining layer 160 and the light emitting structures 170. The second electrode EL2 may include transmissive material when the organic light emitting display apparatus is a top emission type. For example, the second electrode EL2 may be formed using aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, and so on. These may be used alone or in a combination thereof. In example embodiments, the second electrode EL2 may have a single layer structure or a multi layer structure, which may include a metal film, an alloy film, a metal nitride film, a conductive metal oxide film and/or a transparent conductive film.

According to the display apparatus of the example embodiment, since the conductive layer 110 to which a ground voltage is applied is disposed under the active pattern ACT of the thin film transistor TFT, electrical characteristics of the thin film transistor TFT may be stabilized, and display quality of the display apparatus can be improve. In addition, since the conductive layer 110 is an n+amorphous silicon (n+a-Si) layer formed corresponding to the entire surface of the base substrate 100, and does not require an additional patterning process, the conductive layer 110 can be formed by the same process as the buffer layer 120 disposed on the conductive layer 110; thereby, a display apparatus formed by a simplified manufacturing process can be provided.

In addition, in the example embodiments, the display apparatus is an OLED display including a light emitting structure, but the present inventive concept is not limited thereto. For example, the display apparatus may be a liquid crystal display including the thin film transistor TFT and the conductive layer 110 formed through the low temperature polysilicon process.

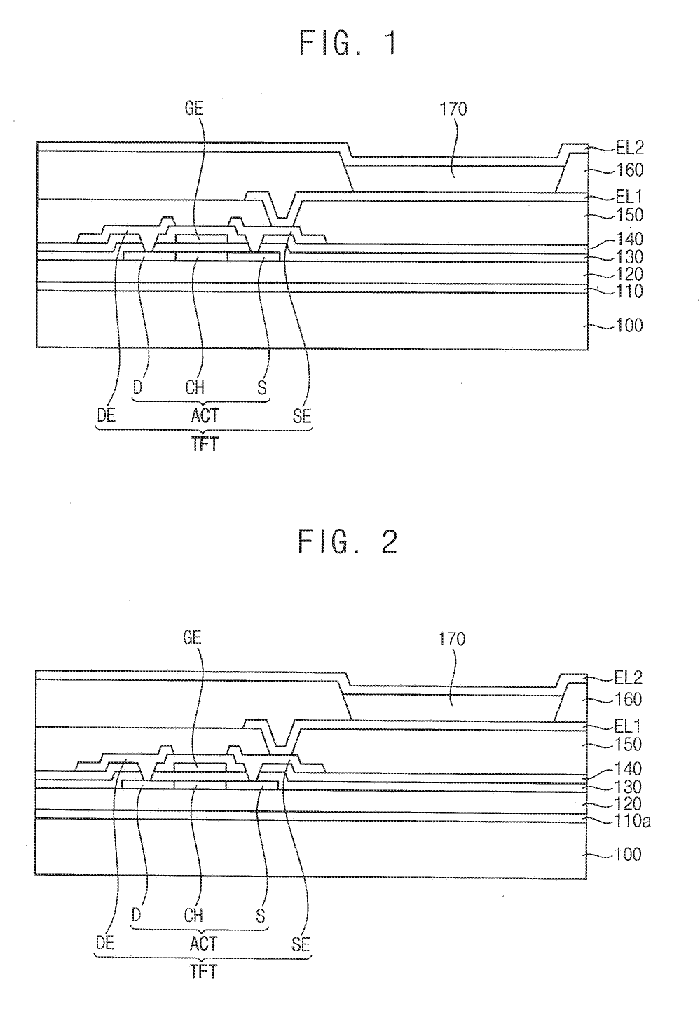

FIG. 2 is a cross-sectional view illustrating a display apparatus according to an example embodiment of the inventive concept.

Referring to FIG. 2, the display apparatus may be substantially the same as the display apparatus of FIG. 1 except for a conductive layer 110a. Therefore, repeated description will be omitted.

The display apparatus may include a base substrate 100, a conductive layer 110a, a buffer layer 120, an active pattern ACT, a first insulation layer 130, a gate pattern, a second insulation layer 140, a data pattern, a planarization layer 150, a first electrode EL1, a pixel defining layer 160, a light emitting structure 170 and a second electrode EL2.

The conductive layer 110a may be a polysilicon (Poly-Si) layer doped with impurities and having conductivity. The polysilicon (Poly-Si) layer may be formed by first depositing amorphous silicon and then crystallizing the amorphous silicon. And then, the polysilicon layer may be doped with impurities to make the polysilicon layer conductive.

In this case as well, the conductive layer 110a may have conductivity, as in the embodiment of FIG. 1. The conductive layer 110a may have a carrier concentration of 1*10¹⁰ (ions/cm³) or more. Preferably, the conductive layer 110a may have a carrier concentration of 1*10¹⁵ (ions/cm³) or more.

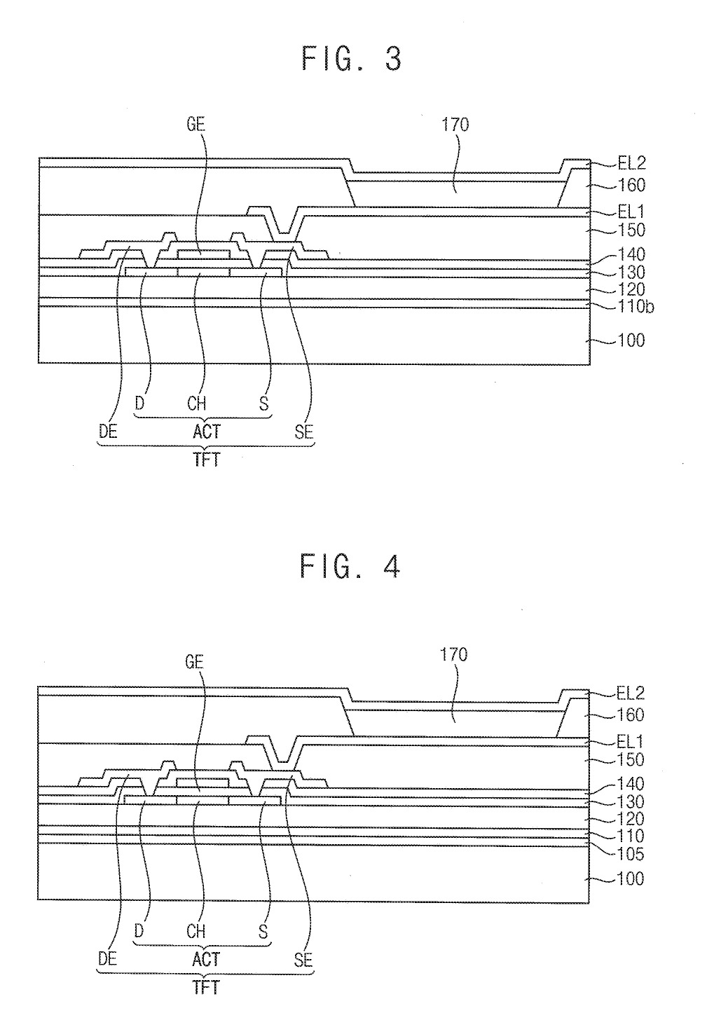

FIG. 3 is a cross-sectional view illustrating a display apparatus according to an example embodiment of the inventive concept.

Referring to FIG. 3, the display apparatus may be substantially the same as the display apparatus of FIG. 1 except for a conductive layer 110b. Therefore, repeated description will be omitted.

The display apparatus may include a base substrate 100, a conductive layer 110c, a buffer layer 120, an active pattern ACT, a first insulation layer 130, a gate pattern, a second insulation layer 140, a data pattern, a planarization layer 150, a first electrode EL1, a pixel defining layer 160, a light emitting structure 170 and a second electrode EL2.

The conductive layer 110b may include a transparent conductive material. For example, the conductive layer 110b may include indium tin oxide (ITO) or indium zinc oxide (IZO). Since the conductive layer 110b is formed of the transparent conductive material, the conductive layer 110c may have conductivity.

The conductive layer 110b may have a carrier concentration of 1*10¹⁰ (ions/cm³) or more. Preferably, the conductive layer 110b may have a carrier concentration of 1*10¹⁵ (ions/cm³) or more.

FIG. 4 is a cross-sectional view illustrating a display apparatus according to an example embodiment of the inventive concept.

Referring to FIG. 4, the display apparatus may be substantially the same as the display apparatus of FIG. 1 except for a lower buffer layer 105. Therefore, repeated description is omitted.

The display apparatus may include a base substrate 100, a lower buffer layer 105, a conductive layer 110, a buffer layer 120, an active pattern ACT, a first insulation layer 130, a gate pattern, a second insulation layer 140, a data pattern, a planarization layer 150, a first electrode EL1, a pixel defining layer 160, a light emitting structure 170 and a second electrode EL2.

The lower buffer layer 105 may be disposed on the base substrate 100. Thus, the lower buffer layer 105 may be disposed between the base substrate 100 and the conductive layer 110. The lower buffer layer 105 may be formed on the base substrate 100 when the conductive layer 110 is difficult to be formed directly on the base substrate 100 (for example, when the base substrate 100 is a glass substrate), so that the conductive layer 110 can be uniformly formed. The lower buffer layer 105 may include silicon oxide (SiOx), silicon nitride (SiNx), silicon oxynitride (SiOxNy), silicon oxycarbide (SiOxCy), silicon carbon nitride (SiCxNy), and so on.

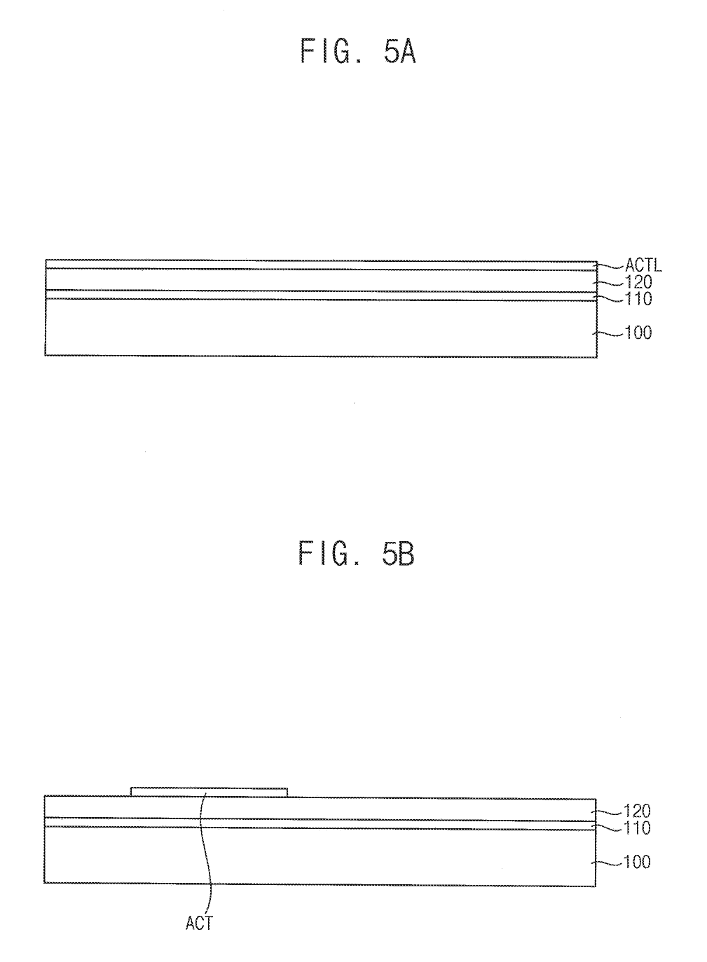

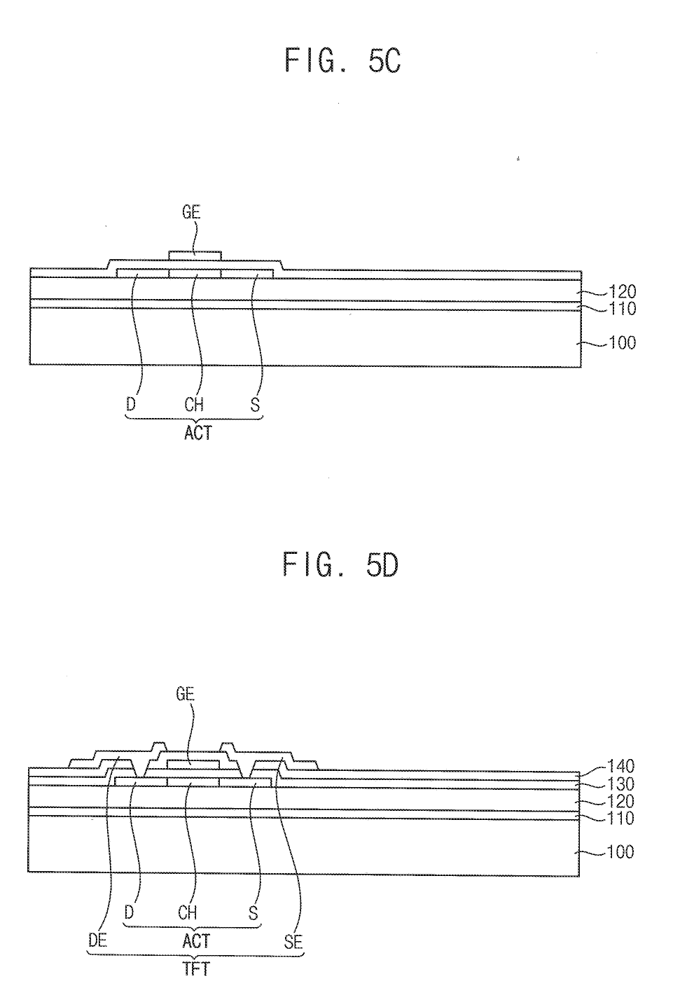

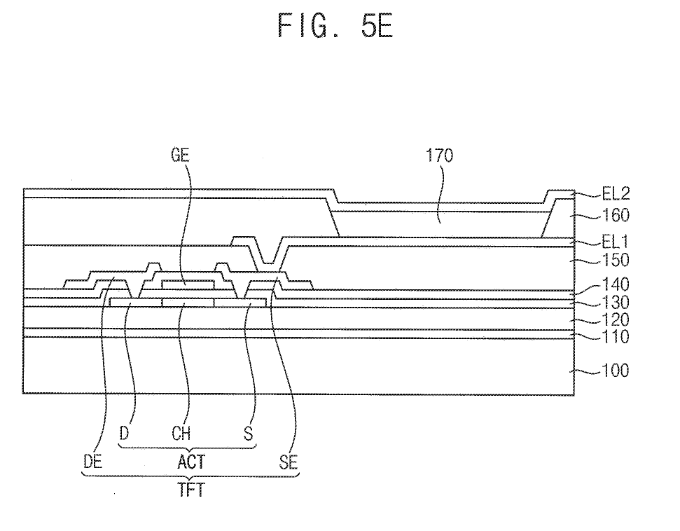

FIGS. 5A, 5B, 5C, 5D, and 5E are cross-sectional views illustrating a method of manufacturing the display apparatus of FIG. 1.

Referring to FIG. 5A, a conductive layer 110 may be formed on a base substrate 100. A buffer layer 120 may be formed on the conductive layer 110. An active layer ACTL may be formed on the buffer layer 120.

The conductive layer 110 may be formed by a deposition process. For example, by depositing amorphous silicon on the base substrate 100 together with a phosphorus containing gas, the conductive layer 110 may be formed. The deposition process may be a chemical vapor deposition (CVD) process, a plasma enhanced chemical vapor deposition (PECVD) process, or the like.

The buffer layer 120 may be formed by a deposition process. For example, by depositing silicon compound on the conductive layer 110, the buffer layer 120 may be formed. The deposition process may be a CVD process, a PECVD process, or the like.

The active layer ACTL may be formed by a deposition process. For example, by depositing amorphous silicon on the buffer layer 120, the active layer ACTL may be formed. The deposition process may be a CVD process, a PECVD process, or the like.

Here, since all of the conductive layer 110, the buffer layer 120 and the active layer ACTL can be formed using the deposition process, the conductive layer 110, the buffer layer 120, and the active layer ACTL may be formed in a continuous process by changing only the deposition gas in a state where the base substrate 100 is disposed in a same chamber. Thus, process efficiency can be improved.

Referring to FIG. 5B, the amorphous silicon forming the active layer ACTL may be crystallized to form an active layer including polysilicon (Poly-Si). Here, the amorphous silicon may be formed by a rapid thermal annealing (RTA) process, a solid phase crystallization (SPC) process, an excimer laser annealing (ELA) process, a metal induced crystallization (MIC) process, a metal induced lateral crystallization (MILC) process, and the like. And then, the active layer ACTL may be patterned to form an active pattern ACT on the buffer layer 120.

Referring to FIG. 5C, a first insulation layer 130 may be formed on the buffer layer 120 on which the active pattern ACT is disposed. The first insulation layer 130 may be formed by a CVD process, a spin coating process, a PECVD process, a sputtering process, a vacuum evaporation process, a high density plasma-chemical vapor deposition (HDP-CVD) process, a printing process, and so on.

A gate pattern including a gate electrode GE may be formed on the first insulating layer 130. In example embodiments, a conductive layer (not illustrated) may be formed on the first insulation layer 130, and then the conductive layer may be partially etched by a photolithography process or an etching process using an additional etching mask. Hence, the gate pattern may be provided on the first insulation layer 130. The conductive layer may be formed by a printing process, a sputtering process, a CVD process, a pulsed laser deposition (PLD) process, a vacuum evaporation process, an atomic layer deposition (ALD) process, and so on.

Thereafter, a source region S and a drain region D may be formed by doping a portion of the polysilicon pattern with an impurity.

Referring to FIG. 5D, a second insulating layer 140 may be formed on the first insulating layer 130 on which the gate pattern is formed. The second insulation layer 140 may be formed by a CVD process, a spin coating process, a PECVD process, a sputtering process, a vacuum evaporation process, a HDP-CVD process, a printing process, and so on.

The second insulating layer 140 and the first insulating layer 130 may be partially removed to form a contact hole. And then, a data pattern including a source electrode SE and a drain electrode DE may be formed on the second insulating layer 140. In example embodiments, a conductive layer (not illustrated) may be formed on the second insulating layer 140, and then the conductive layer may be partially etched by a photolithography process or an etching process using an additional etching mask. Hence, the data pattern may be provided on the second insulation layer 140. The conductive layer may be formed by a printing process, a sputtering process, a CVD process, a pulsed laser deposition (PLD) process, a vacuum evaporation process, an atomic layer deposition (ALD) process, and so on. Accordingly, a thin film transistor TFT including the gate electrode DE, the active pattern ACT, the source electrode SE and the drain electrode DE may be formed.

Referring to FIG. 5E, a planarization layer 150 may be formed on the second insulation layer 140 on which the data pattern is formed. In example embodiments, a planarization process may be executed on the planarization layer 150 to enhance the flatness of the planarization layer 150. For example, the planarization layer 150 may have a substantially level surface by a chemical mechanical polishing (CMP) process, an etch-back process, and so on.

The planarization layer 150 may be obtained by a spin coating process, a printing process, a sputtering process, a CVD process, an ALD process, a PECVD process, an HDP-CVD process or a vacuum evaporation process in accordance with ingredients included in the third insulation layer 150. The planarization layer 150 may be partially etched to form a contact hole exposing the source electrode SE.

A first electrode EL1 may be formed on the planarization layer 150. In example embodiments, a conductive layer (not illustrated) may be formed on the planarization layer 150, and then the conductive layer may be partially etched by a photolithography process or an etching process using an additional etching mask. Hence, the first electrode EL1 may be provided on the planarization layer 150. The conductive layer may be formed by a printing process, a sputtering process, a CVD process, a PLD process, a vacuum evaporation process, an ALD process, and so on. The first electrode EL1 may be electrically connected to the thin film transistor TFT through the contact hole formed through the planarization layer 150.

A pixel defining layer 160 may be formed on the planarization layer 150 on which the first electrode EL1 is formed. The pixel defining layer 160 may be obtained by a spin coating process, a spray process, a printing process, a CVD process, and so on.

A light emitting structure 170 may be formed on the first electrode PE 1 exposed through an opening of the pixel defining layer 160. The light emitting structure 170 may be obtained using a laser transfer process, a printing process, or the like.

A second electrode EL 2 may be formed on the pixel defining layer 160 and the light emitting structure 170. The second electrode EL 2 may be formed by a printing process, a sputtering process, a CVD process, a PLD process, a vacuum evaporation process, and/or an ALD process, and so on.

Although not shown, a sealing substrate or a thin film encapsulation (TFE) may be further provided on the second electrode EL2 to prevent penetration of outside air and moisture into the display apparatus if necessary.

Accordingly, the display apparatus may be manufactured. According to the example embodiments, since the conductive layer 110, the buffer layer 120, and the active layer ACTL can be formed by a continuous deposition process in the same chamber, the manufacturing process efficiency can be improved.

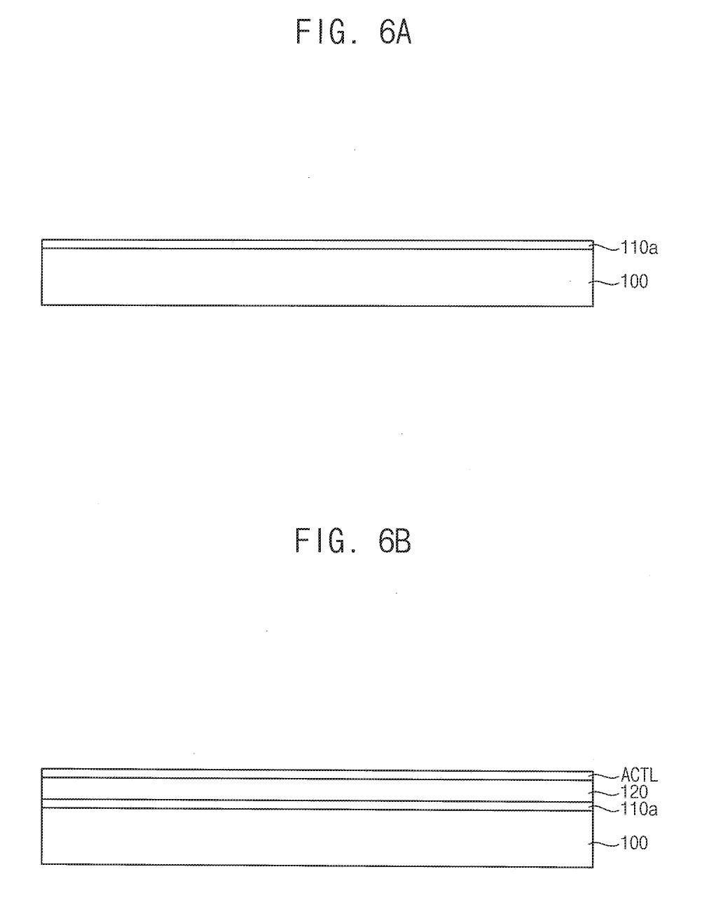

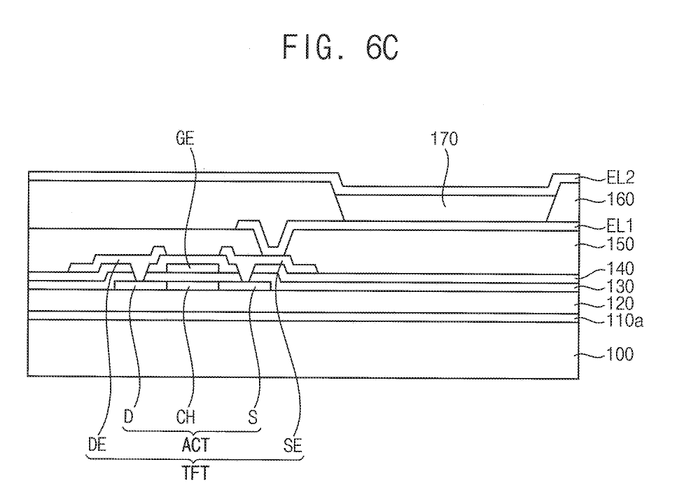

FIGS. 6A, 6B and 6C are cross-sectional views illustrating a method of manufacturing the display apparatus of FIG. 2. The method may be substantially the same as the method of FIGS. 5A to 5E, except for forming a conductive layer 110a. Therefore, repeated description will be omitted.

Referring to FIG. 6A, a conductive layer 110a may be formed on a base substrate 100. A polysilicon (Poly-Si) layer may be formed, and then the polysilicon layer may be doped with impurities to form the conductive layer 110a. The conductive layer 110a may be formed by various known methods.

Referring to FIG. 6B, a buffer layer 120 may be formed on the conductive layer 110a. An active layer ACTL may be formed on the buffer layer 120.

The buffer layer 120 may be formed by a deposition process. For example, by depositing silicon compound on the conductive layer 110, the buffer layer 120 may be formed.

The active layer ACTL may be formed by a deposition process. For example, by depositing amorphous silicon on the buffer layer 120, the active layer ACTL may be formed.

Here, since the buffer layer 120 and the active layer ACTL can be formed using the deposition process, the buffer layer 120 and the active layer ACTL may be formed in a continuous process by changing only the deposition gas in a state where the base substrate 100 is disposed in a same chamber.

Referring to FIG. 6C, the amorphous silicon forming the active layer ACTL may be crystallized to form an active layer including polysilicon (Poly-Si). Then, the active layer ACTL may be patterned to form an active pattern ACT on the buffer layer 120.

A first insulation layer 130 may be formed on the buffer layer 120 on which the active pattern ACT is disposed. A gate pattern including a gate electrode GE may be formed on the first insulating layer 130. Thereafter, a source region S and a drain region D may be formed by doping a portion of the polysilicon pattern with an impurity.

A second insulating layer 140 may be formed on the first insulating layer 130 on which the gate pattern is formed. The second insulating layer 140 and the first insulating layer 130 may be partially removed to form a contact hole. Then, a data pattern including a source electrode SE and a drain electrode DE may be formed on the second insulating layer 140.

Accordingly, a thin film transistor TFT including the gate electrode DE, the active pattern ACT, the source electrode SE and the drain electrode DE may be formed.

A planarization layer 150 may be formed on the second insulation layer 140 on which the data pattern is formed. A first electrode EL1 may be formed on the planarization layer 150. A pixel defining layer 160 may be formed on the planarization layer 150 on which the first electrode EL1 is formed. A light emitting structure 170 may be formed on the first electrode PE 1 exposed through an opening of the pixel defining layer 160. A second electrode EL 2 may be formed on the pixel defining layer 160 and the light emitting structure 170. Accordingly, the display apparatus may be manufactured.

Although not shown, a manufacturing method of the display apparatus of FIG. 3 may be substantially the same as the method of FIGS. 6A to 6C, except for forming a conductive layer (see 110b in FIG. 3) including a transparent conductive material such as indium tin oxide (ITO) or indium zinc oxide (IZO) instead of the conductive layer 110a. The conductive layer 110b including the transparent conductive material may be formed by various known methods.

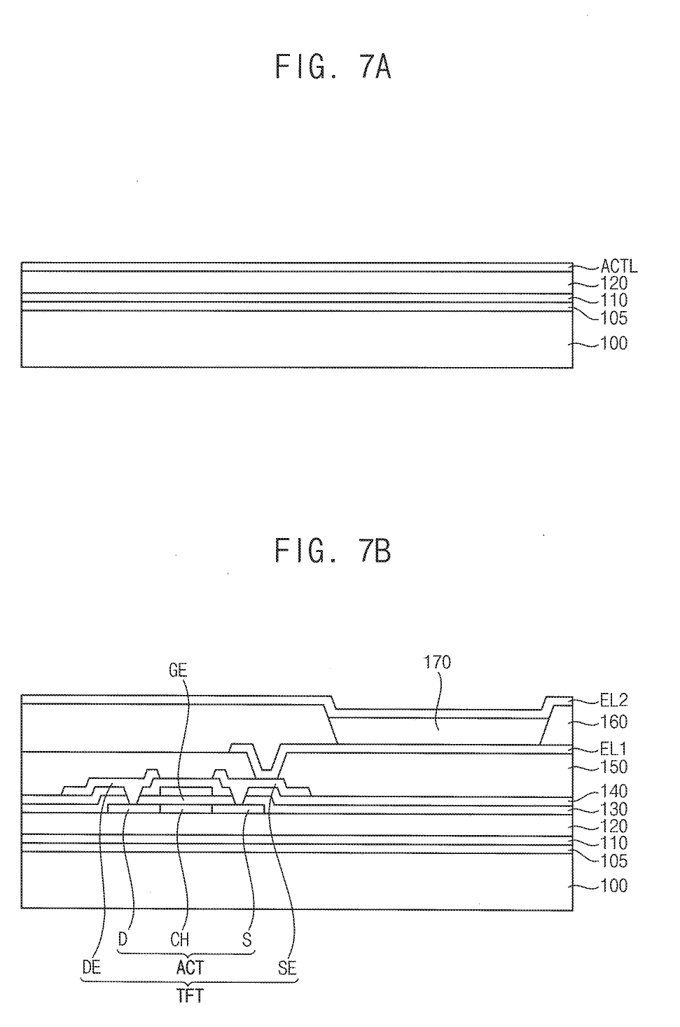

FIGS. 7A and 7B are cross-sectional views illustrating a method of manufacturing the display apparatus of FIG. 4. The method may be substantially the same as the method of FIGS. 5A to 5E, except for further forming a lower buffer layer 105. Therefore, repeated description will be omitted.

Referring to FIG. 7A, a lower buffer layer 105 may be formed on a base substrate 100. A conductive layer 110 may be formed on the lower buffer layer 105. A buffer layer 120 may be formed on the conductive layer 110. An active layer ACTL may be formed on the buffer layer 120.

The lower buffer layer 105 may be formed by a deposition process. For example, by depositing silicon compound on the base substrate 100, the lower buffer layer 105 may be formed. The deposition process may be a CVD process, a PECVD process, or the like.

The conductive layer 110 may be formed by a deposition process. The buffer layer 120 may be formed by a deposition process. The active layer ACTL may be formed by a deposition process.

Here, since all of the lower buffer layer 105, the conductive layer 110, the buffer layer 120 and the active layer ACTL can be formed using the deposition process, the lower buffer layer 105, the conductive layer 110, the buffer layer 120, and the active layer ACTL may be formed in a continuous process by changing only the deposition gas in a state where the base substrate 100 is disposed in a same chamber. Thus, process efficiency can be improved.

Referring to FIG. 7B, the amorphous silicon forming the active layer ACTL may be crystallized to form an active layer including polysilicon (Poly-Si). And then, the active layer ACTL may be patterned to form an active pattern ACT on the buffer layer 120.

A first insulation layer 130 may be formed on the buffer layer 120 on which the active pattern ACT is disposed. A gate pattern including a gate electrode GE may be formed on the first insulating layer 130. Thereafter, a source region S and a drain region D may be formed by doping a portion of the polysilicon pattern with an impurity.

A second insulating layer 140 may be formed on the first insulating layer 130 on which the gate pattern is formed. The second insulating layer 140 and the first insulating layer 130 may be partially removed to form a contact hole. And then, a data pattern including a source electrode SE and a drain electrode DE may be formed on the second insulating layer 140.

Accordingly, a thin film transistor TFT including the gate electrode DE, the active pattern ACT, the source electrode SE and the drain electrode DE may be formed.

A planarization layer 150 may be formed on the second insulation layer 140 on which the data pattern is formed. A first electrode EL1 may be formed on the planarization layer 150. A pixel defining layer 160 may be formed on the planarization layer 150 on which the first electrode EL1 is formed. A light emitting structure 170 may be formed on the first electrode PE 1 exposed through an opening of the pixel defining layer 160. A second electrode EL 2 may be formed on the pixel defining layer 160 and the light emitting structure 170. Accordingly, the display apparatus may be manufactured.

According to the example embodiments of the present inventive concept, a display apparatus includes a base substrate, a conductive layer disposed on the base substrate to cover entire of the base substrate, wherein a ground voltage or voltage of 0 V is applied, a buffer layer disposed on the conductive layer, an active pattern comprising a drain region, a source region and a channel region between the drain region and the source region, a first insulation layer disposed on the active pattern, a gate pattern disposed on the first insulation layer and comprising a gate electrode which overlaps the channel region of the active pattern, a second insulation layer disposed on the gate pattern, and a data pattern comprising a source electrode electrically connected to the source region of the active pattern, and a drain electrode electrically connected to the drain region of the active pattern. Since the conductive layer to which the ground voltage is applied is located under the active pattern of the thin film transistor, electrical characteristics of the thin film transistor are stabilized, and the display quality of the display apparatus can be improved.

In addition, the conductive layer is an n+amorphous silicon (n+a-Si) layer formed corresponding to the entire surface of the base substrate, and does not require a additional patterning process, the conductive layer can be formed by the same process as the buffer layer disposed on the conductive layer, thereby a display apparatus formed by a simplified manufacturing process can be provided.

The foregoing is illustrative of the inventive concept and is not to be construed as limiting thereof. Although a few example embodiments of the inventive concept have been described, those skilled in the art will readily appreciate that many modifications are possible in the example embodiments without materially departing from the novel teachings and advantages of the inventive concept. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, it is to be understood that the foregoing is illustrative of the inventive concept and is not to be construed as limited to the specific example embodiments disclosed, and that modifications to the disclosed example embodiments, as well as other example embodiments, are intended to be included within the scope of the appended claims. The inventive concept is defined by the following claims, with equivalents of the claims to be included therein.

What is claimed is:

1. A display apparatus, comprising:
a base substrate;
a conductive layer disposed on the base substrate to cover an entirety of the base substrate, wherein the conductive layer is configured to be applied with a ground voltage;
a buffer layer disposed on the conductive layer;
an active pattern comprising a drain region, a source region, and a channel region between the drain region and the source region;
a first insulation layer disposed on the active pattern;
a gate pattern disposed on the first insulation layer and comprising a gate electrode overlapping the channel region of the active pattern;
a second insulation layer disposed on the gate pattern; and
a data pattern comprising a source electrode electrically connected to the source region of the active pattern, and a drain electrode electrically connected to the drain region of the active pattern.

2. The display apparatus of claim 1, wherein the active pattern comprises crystallized polysilicon (poly-Si).

3. The display apparatus of claim 2, wherein the conductive layer is an n+ doped amorphous silicon (n+a-Si) layer.

4. The display apparatus of claim 3, wherein the conductive layer has a carrier concentration of 1*10¹⁵ (ions/cm³) or more.

5. The display apparatus of claim 3, wherein the buffer layer comprises a silicon compound.

6. The display apparatus of claim 5, wherein the base substrate is a polyimide (PI) resin film.

7. The display apparatus of claim 5, further comprising:
a lower buffer layer disposed between the base substrate and the conductive layer, and comprising a silicon compound.

8. The display apparatus of claim 1, wherein the active pattern, the gate electrode, the source electrode, and the drain electrode form a thin film transistor, and
wherein the display apparatus further comprises:
a first electrode electrically connected to the thin film transistor;
a second electrode facing the first electrode; and
a light emitting structure disposed between the first electrode and the second electrode.

9. The display apparatus of claim 1, wherein the conductive layer comprises polysilicon (poly-Si) doped with impurities.

10. The display apparatus of claim 1, wherein the conductive layer comprises indium tin oxide (ITO) or indium zinc oxide (IZO).

11. A method of manufacturing a display apparatus, the method comprising:
forming a conductive layer on a base substrate to cover an entirety of the base substrate;
forming, in a chamber by a deposition process, a buffer layer which comprises a silicon compound on the conductive layer;
forming, in the chamber by a deposition process, an active layer which comprises an amorphous silicon on the buffer layer;
crystallizing the amorphous silicon to form an active pattern comprising polysilicon (poly-Si); and
forming a first insulation layer on the active pattern.

12. The method of claim 11, wherein in forming the conductive layer,
the conductive layer is formed by depositing amorphous silicon together with a phosphorus containing gas on the base substrate.

13. The method of claim 12, wherein the conductive layer, the buffer layer, and the active layer are formed by a continuous deposition process in a same chamber.

14. The method of claim 13, wherein the base substrate is a polyimide (PI) resin film.

15. The method of claim 13 further comprising forming, before forming the conductive layer, a lower buffer layer comprising a silicon compound on the base substrate, and
wherein the conductive layer is formed on the lower buffer layer.

16. The method of claim 11, wherein the conductive layer has a carrier concentration of 1*10¹⁵ (ions/cm³) or more.

17. The method of claim 16, wherein the conductive layer comprises one of polysilicon (poly-Si) doped with impurities, indium tin oxide (ITO), and indium zinc oxide (IZO).

18. The method of claim 11, wherein forming the active pattern comprises:
forming a polysilicon layer comprising polysilicon (poly-Si) by crystallizing the amorphous silicon; and
patterning the polysilicon layer to form the active pattern.

19. The method of claim 11, further comprising:
forming a gate electrode on the first insulation layer;
forming a drain region and a source region by doping impurities to a portion of the active pattern;
forming a second insulation layer on the gate electrode; and
forming a source electrode and a drain electrode on the second insulation layer.

20. The method of claim 11, further comprising:
forming a planarization layer on the source electrode and the drain electrode;
forming a first electrode on the planarization layer;
forming a pixel defining layer, which defines an opening to expose the first electrode, on the planarization layer;
forming a light emitting structure on the first electrode on which the pixel defining layer is formed; and
forming a second electrode on the light emitting structure.
